(19) United States
(12) Patent Application Publication
(10) Pub. No.: US 2026/0235640 A1
(43) Pub. Date: Aug. 13, 2026

(54) MAGNETO-MECHANICAL ACCELEROMETER

(71) Applicants: UNIVERSITA' DEGLI STUDI DI MESSINA, MESSINA (IT); POLITECNICO DI BARI, BARI (IT)

(72) Inventors: Giovanni FINOCCHIO, MESSINA (IT); Francesca GARESCI', MESSINA (IT); Eleonora RAIMONDO, TERME VIGLIATORE (IT); Mario CARPENTIERI, BOLOGNA (IT); Andrea MEO, SOLARO (IT); Davi RÖHE SALOMON DA ROSA RODRIGUES, BARI (IT); Vito PULIAFITO, BARCELLONA POZZO DI GOTTO (IT)

(21) Appl. No.: 19/155,683

(22) PCT Filed: Feb. 13, 2024
(86) PCT No.: PCT/IB2024/051311

§ 371 Date: Aug. 12, 2025

(30) Foreign Application Priority Data
Feb. 13, 2023 (IT) 102023000002433

(51) Int. Cl. G01P 15/105; G01P 15/08; G01R 33/09

(52) U.S. Cl. CPC G01P 15/105; G01P 15/0885; G01P 15/0894; G01R 33/091; G01R 33/098

(57) ABSTRACT

Magneto-mechanical accelerometer (10) comprising a first magnetic tunnel junction (11) fixedly mounted, and a magnetic component mounted movable with respect to the first junction (11), so as to be able to approach/move away from it during the acceleration phases to which the accelerometer is subject. The magnetic component is a further magnetic tunnel junction (12) or a permanent magnet. The first junction (11) and the magnetic component are coupled mechanically and magnetically. The accelerometer further comprises a processing circuit.

### FIELD OF THE ART

The present invention relates to an accelerometer based on spintronic technology and to a method of measuring acceleration by means of such an accelerometer.

### PRIOR ART

Accelerometers are currently used in many devices to monitor acceleration.

In general, it is desirable that the acceleration measured by an accelerometer provides a valid input for identifying events in the environment in which the accelerometer is used. For example, an airbag may be activated once a certain acceleration threshold is reached, or the display in a portable device may be oriented based on how it is moved by a user.

Currently, the main types of accelerometers include both capacitive devices based on MEMS (Micro Electro-Mechanical Systems), which generate a voltage when the distance between the plates of a capacitor changes due to an acceleration, and piezoelectric displacement transducers, which generate an electric voltage following the deformation induced by an acceleration.

Known accelerometers that include MEMS-based capacitive devices have the problem of being affected by electromagnetic disturbances and are not easily scalable to sub-micrometric dimensions, while those that include piezoelectric displacement transducers are mechanically weak.

The object of the invention is to provide an accelerometer that overcomes the drawbacks of the prior art.

A further object of the invention is to provide a highly sensitive accelerometer.

Another object of the invention is to provide an accelerometer that is easily scalable and can be integrated with current high-density technologies such as CMOS (Complementary metal-oxide-semiconductor).

These and other objects are achieved with the magneto-mechanical accelerometer as claimed in the appended claims.

### DESCRIPTION OF THE INVENTION

The magneto-mechanical accelerometer according to the invention comprises at least one first fixedly mounted magnetic tunnel junction comprising a free ferromagnetic layer and a reference ferromagnetic layer.

The accelerometer further comprises a magnetic component mounted movable with respect to the aforementioned at least one first magnetic tunnel junction, so as to be able to approach/move away from the at least one first magnetic tunnel junction during the acceleration phases to which the accelerometer is subject.

The magnetic component is a further magnetic tunnel junction or a permanent magnet.

The at least one first magnetic tunnel junction and the magnetic component are coupled mechanically, by elastic means, and magnetically, by the dipole interaction due to the magnetostatic fields generated by them.

The accelerometer further comprises a processing circuit configured to:
apply to the at least one first magnetic tunnel junction a voltage and/or direct electric current sufficient to activate the self-oscillating operation regime of the magnetization of its free ferromagnetic layer,
apply an alternating electric current to the at least one first magnetic tunnel junction such as to induce an injection-locking state in the at least one first magnetic tunnel junction and induce a rectification voltage to the ends of the at least one first magnetic tunnel junction, thanks to the spintronic diode effect,
measure the rectification voltage at the ends of the at least one first magnetic tunnel junction, and
determine the acceleration on the basis of the measured rectification voltage.

The processing circuit is configured to determine the acceleration on the basis of the rectification voltage by comparing, preferably, the variation of the rectification voltage with respect to a reference rectification voltage measured in the absence of acceleration.

Preferably, in the at least one first magnetic tunnel junction, the reference ferromagnetic layer has fixed magnetization lying parallel to the same reference ferromagnetic layer, and the free ferromagnetic layer has stable magnetization in a direction perpendicular to the same free and variable ferromagnetic layer in response to external stimuli.

If the magnetic component is a further magnetic tunnel junction, in such further magnetic tunnel junction, preferably, a reference ferromagnetic layer has fixed magnetization lying parallel to the Same reference ferromagnetic layer, and a free ferromagnetic layer has stable magnetization in a direction perpendicular to the same free and variable ferromagnetic layer in response to external stimuli.

Furthermore, the processing circuit is configured to apply to the further magnetic tunnel junction a voltage and/or direct electric current sufficient to activate the self-oscillating operating regime of the magnetization of the free ferromagnetic layer of the further magnetic tunnel junction and such as to induce a mutual injection-locking state in which the oscillation of the magnetization of the free ferromagnetic layer of the further magnetic tunnel junction is synchronized with the oscillation of the magnetization of the free ferromagnetic layer of the at least one first magnetic tunnel junction.

Preferably, the accelerometer comprises, in addition to the first magnetic tunnel junction, a second fixedly mounted magnetic tunnel junction. In this case, the movable magnetic component is arranged between the first and second magnetic tunnel junctions, in such a way that the first and second magnetic tunnel junctions and the magnetic component are substantially aligned and the magnetic component can move, during the acceleration phases to which the accelerometer is subjected, along the direction joining the first and second magnetic tunnel junctions.

Preferably, the accelerometer comprises, in addition to the first magnetic tunnel junction, a second, a third and a fourth fixedly mounted magnetic tunnel junction. The first, second, third and fourth magnetic tunnel junctions are arranged in pairs aligned along two mutually orthogonal directions. The magnetic component is placed in a central position with respect to the first, second, third and fourth magnetic tunnel junction, in such a way that the magnetic component can move, during the acceleration phases to which the accelerometer is subjected, in a plane along the two mutually orthogonal directions joining the first and second magnetic tunnel junctions and the third and fourth magnetic tunnel junctions respectively.

Preferably, the accelerometer comprises, in addition to the first magnetic tunnel junction, a second, third, fourth, fifth and sixth fixedly mounted magnetic tunnel junction. The first, second, third, fourth, fifth and sixth magnetic tunnel junctions are arranged in pairs aligned along three mutually orthogonal directions. The magnetic component is placed in a central position with respect to the first, second, third, fourth, fifth and sixth magnetic tunnel junction, in such a way that the magnetic component can move, during the acceleration phases to which the accelerometer is subjected, in the space along the three mutually orthogonal directions joining respectively the first and second magnetic tunnel junction, the third and fourth magnetic tunnel junction and the fifth and sixth magnetic tunnel junction.

Preferably, the magnetic tunnel junctions of the accelerometer are connected to independent electrodes.

The method for measuring acceleration using the magneto-mechanical accelerometer as described above comprises the steps of:
applying to the at least one first magnetic tunnel junction a voltage and/or direct electric current sufficient to activate the self-oscillating operating regime of the magnetization of the free ferromagnetic layer of the at least one first magnetic tunnel junction,
applying to the at least one first magnetic tunnel junction an alternating electric current such as to induce an injection-locking state in the at least one first magnetic tunnel junction and induce a rectifying voltage in its ends, thanks to the spintronic diode effect,
bringing the magnetic component closer to/away from the at least one first magnetic tunnel junction during the acceleration phases to which the accelerometer is subject,
measuring the rectification voltage at the ends of the at least one first magnetic tunnel junction;
determining the acceleration on the basis of the measured rectification voltage.

Preferably, the step of determining the acceleration on the basis of the rectification voltage comprises comparing the change in rectification voltage with respect to a reference rectification voltage measured in the absence of acceleration.

### SUMMARY DESCRIPTION OF DRAWINGS

These and other characteristics and advantages of the present invention will become clear from the following description of preferred embodiments made by way of example and not limitation with the aid of the accompanying figures, in which elements indicated with the same or a similar numerical reference indicate elements having the same or similar functionality and construction and in which:

FIG. 1 represents a schematic view of a magneto-mechanical accelerometer according to an embodiment of the present invention;

FIG. 2a represents a schematic view of an example of a tunnel junction usable in a magneto-mechanical accelerometer according to the various embodiments of the present invention;

FIG. 2b represents a schematic view of a further example of a tunnel junction usable in a magneto-mechanical accelerometer according to the various embodiments of the present invention;

FIG. 3 shows a graph of the tension measured at the ends of the fixed junction and the relative displacement of the movable junction with respect to the fixed junction, both as a function of time, in response to a time-varying external acceleration, in the accelerometer of FIG. 1;

FIG. 4 shows a graph of the tension measured on the end(s) of the fixed junction as a function of the distance between the fixed junction and the movable junction, in the accelerometer of FIG. 1;

FIG. 5 represents a schematic view of a magneto-mechanical accelerometer according to a further embodiment of the present invention;

FIG. 6 represents a schematic view of a magneto-mechanical accelerometer according to a further embodiment of the present invention.

### DESCRIPTION OF PREFERRED FORMS OF EMBODIMENTS

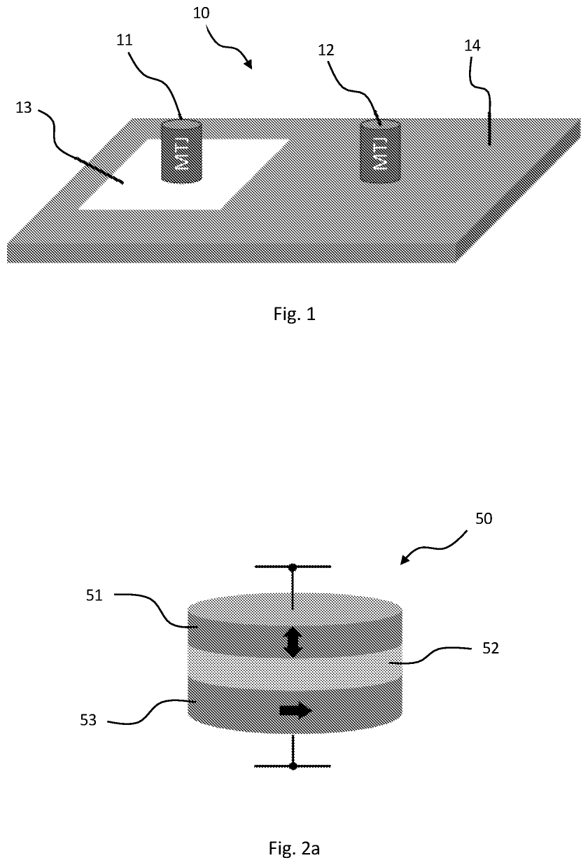

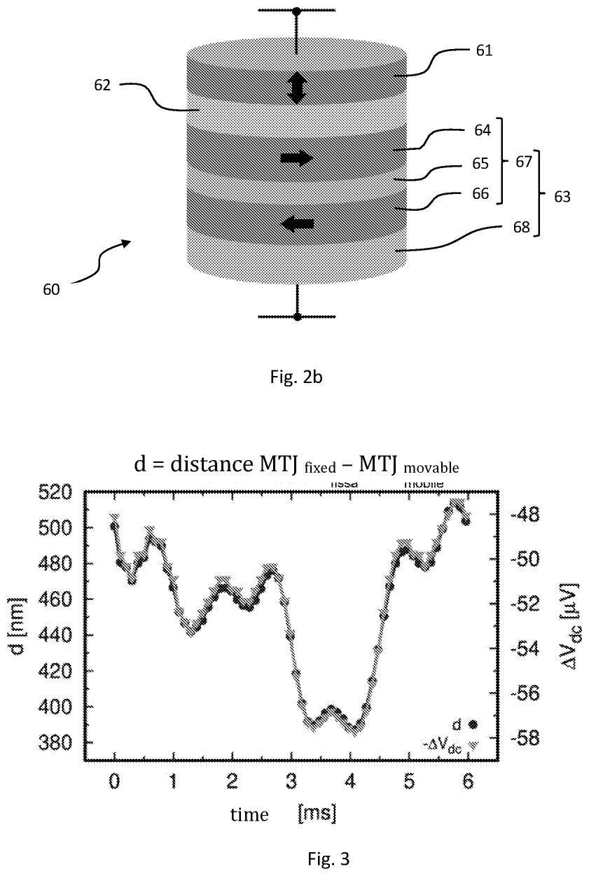

A magneto-mechanical accelerometer 10 according to a first embodiment of the invention is described below with reference to FIGS. 1, 2a and 2b.

The accelerometer 10 comprises a fixedly mounted magnetic tunnel junction (MTJ) 11, hereinafter referred to as a fixed junction for brevity. This fixed junction 11 is mechanically coupled, by elastic means (not shown), to a further magnetic tunnel junction 12, movably mounted with respect to the aforementioned fixed junction 11 and hereinafter referred to, for brevity, as movable junction 12. In particular, the fixed junction 11 is constrained to a support 13 fixedly mounted in a device comprising the accelerometer 10, while the movable junction 12 is constrained to a support 14 movable with respect to the aforementioned fixed support 13. The fixed support 13 and the movable support 14 are mechanically connected, by means of the aforementioned elastic means, in such a way that the movable support 14 can move, under the action of an external acceleration, along the direction joining the movable junction 12 and the fixed junction 11.

With reference to FIG. 2a, a magnetic tunnel junction used in the present invention is indicated at 50 and comprises, for example, a thin intermediate layer 52 of insulating and non-magnetic material (for example MgO), defined as a tunnel barrier, interposed between two ferromagnetic outer layers 51, 53 (for example CoFeB with various percentages of the materials). Of the aforementioned two ferromagnetic layers 51, 53, a first layer 51, called the free layer, has stable magnetization in a direction perpendicular to the same first layer 51, and a second layer 53, called the reference layer, has fixed magnetization lying parallel to the same second layer 53. These magnetizations are schematically represented by arrows in FIG. 2a. The magnetization the free layer 51 evolves dynamically in response to external stimuli (e.g., a magnetic field, a polarized spin electric current). Depending on the relative orientation of the magnetization of the reference layer 53 and the free layer 51, the junction 50 is characterized, in a known way, by different levels of electrical resistance: high resistance levels are detected in the configuration with anti-parallel magnetizations and low resistance levels in the configuration with parallel magnetizations. Such resistance may be measured in terms of voltage at the ends of the junction 50.

Furthermore, in a magnetic tunnel junction 50, the magnetization of the free layer 51 can be induced, in a known manner, in a self-induced oscillatory state under the application of a direct-electric-current (IDC), due to the so-called spin-transfer torque (STT) effect. The frequency of oscillation of the magnetization depends on the amplitude of the input current (IDC). By also applying an alternating electric current (AC) at the same time, the oscillatory rate of the magnetization can be altered. For frequencies of the alternating electric current (_{AC}) close to the self-oscillation frequency of the magnetization of the free layer 51, a coupling between the two excitations may occur, resulting in oscillation of the magnetization of the free layer 51 at the frequency of the alternating electric current (_{AC}). In such a regime, the frequency of oscillation of the magnetization of the free layer 51 remains constant as the direct electric current (IDC) varies, and the junction 50 is in a state that is defined as injection-locking. By varying the direct electric current (IDC), the amplitude and phase of the oscillations of the magnetization of the free layer 51 can be controlled, and a rectification voltage (Vdc) can be generated that depends on the electrical resistance levels of the junction 50 as well as on the amplitude and phase of the oscillations of the magnetization of the free layer 51. This phenomenon is called “spintronic diode effect” and occurs only for a small range of direct electric current (IDC).

Referring to FIG. 2b, a further example of a magnetic tunnel junction 60 usable in the present invention comprises, for example, a thin intermediate layer 62 of insulating and non-magnetic material (e.g. MgO), referred to as a tunnel barrier, interposed between a ferromagnetic outer layer 61 and a composite outer layer 63. The outer ferromagnetic layer 61, defined as a free layer, has a stable magnetization oriented in a direction perpendicular to the same free layer 61, free to respond to external stimuli. The composite outer layer 63 comprises a reference layer 64 (e.g., CoFeB) and a constrained layer 66 (e.g., CoFe), coupled by inserting a thin metal layer 65 (e.g., Ru) by means of the Ruderman-Kittel-Kasuya-Yosida (RKKY) interaction, thereby making a synthetic antiferromagnetic layer 67. The composite layer 63 further comprises an antiferromagnetic layer 68 (e.g. PtMn). The direction of magnetization of the constrained layer 66 may be fixed by coupling the constrained layer 66 with the antiferromagnetic layer 68. The synthetic antiferromagnetic state 67 is designed to have the magnetization oriented in the plane of the layer itself. The magnetizations are schematically represented by arrows in FIG. 2b.

Returning to the embodiment illustrated in FIG. 1, the fixed junction 11 and the movable junction 12 are advantageously connected to independent electrodes, which allow the current/voltage to be applied independently and allow the voltage to be read at the ends of the fixed junction 11 independently.

The fixed junction 11 and the movable junction 12 are also arranged at a distance such as to be magnetically coupled, through the dipole interaction due to the magnetostatic fields generated by their ferromagnetic layers. The movable junction 12 may approach/move away from the fixed junction 11 during the acceleration phases to which the accelerometer 10 (or, equivalently, the device comprising the accelerometer 10) is subjected.

Both the fixed junction 11 and the movable junction 12 of the accelerometer 10 are supplied, by a processing circuit (not shown) of the accelerometer 10, with a voltage and/or direct electric current sufficient to activate, in a known manner, as illustrated above, the self-oscillating operating regime of the magnetization of their free layer. Therefore, both the fixed junction 11 and the movable junction 12 function as spintronic diodes in active mode.

The fixed junction 11 is also powered by an alternating electric current such that the fixed junction 11 is in the injection-locking state and a rectifying voltage is generated at its ends, thanks to the spintronic diode effect explained above.

In particular, according to the present embodiment, the frequency of oscillation of the magnetization of the free layer of the movable junction 12 in the self-oscillation state, induced by the sole introduction of a direct electric current, is different from the frequency of oscillation of the magnetization of the free layer of the fixed junction 11 in the injection-locking state. In such a situation, there are distances between the fixed junction 11 and the movable junction 12 such that the magnetic coupling causes the oscillations of the magnetization in the movable junction 12 to synchronize with the oscillations of the magnetization in the fixed junction 11. Such a condition is called mutual injection-locking state. The aforementioned synchronization induces a change in the phase and/or amplitude of the oscillations of the magnetization of the free layer of the fixed junction 11 which results in a variation of the rectification voltage read at the ends of the fixed junction 11. Advantageously, the synchronization of the oscillations of the magnetization in the movable junction 12 with the oscillations of the magnetization in the fixed junction 11 allows to obtain an accelerometer 10 with a high sensitivity, which can reach a few nanometers, and to miniaturize the accelerometer, with dimensions that can be scaled to the order of a few hundred nanometers. In the absence of an external acceleration acting on the device on which the accelerometer 10 is mounted, the rectification voltage read at the ends of the fixed junction 11 is constant. When the accelerometer 10 is subjected to an acceleration, this causes a variation in the distance between the fixed junction 11 and the movable junction 12, which produces a variation in the magnetic coupling between the junctions, which causes a variation in the rectification voltage ΔVdc at the ends of the fixed junction 11. Based on the variation in rectification voltage ΔVdc detected by the processing circuit at the ends of the fixed junction 11, it is then possible to determine the acceleration that acted on the accelerometer 10.

The graph shown in FIG. 3 shows how the evolution over time—due to the effect of acceleration—of the rectification voltage Vdc read at the ends of the fixed junction 11 depends on the variation of the distance d between the two junctions. This bond is possible thanks to the fact that the dynamics associated with the magnetic transient are much faster than the mechanical ones.

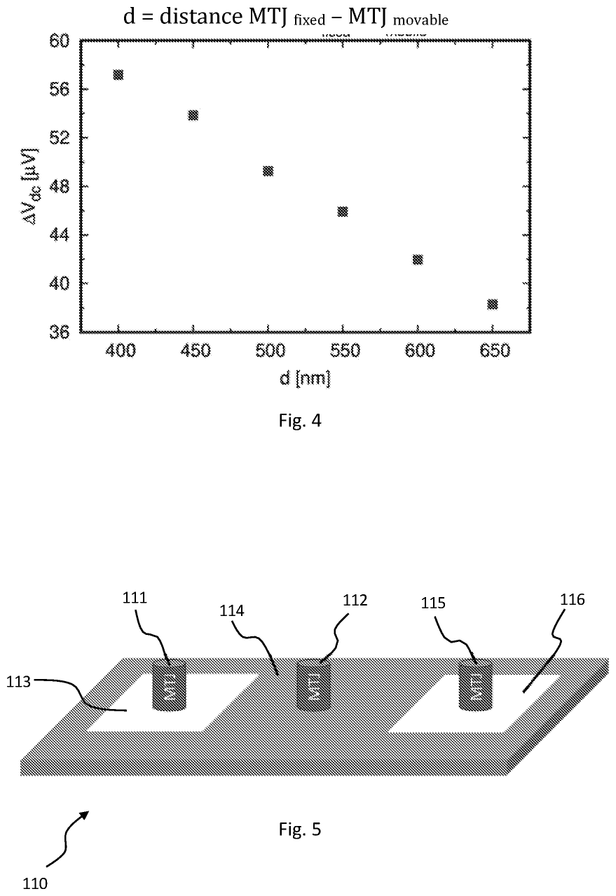

The graph shown in FIG. 4 shows the linear dependence of the rectification voltage ΔVdc measured at the ends of the fixed junction 11 on the distance d between the fixed junction 11 and the movable junction 12. In the aforementioned graph, the reference voltage taken to determine the variation ΔVdc is the voltage measured at the ends of the fixed junction 11 when it is in an injection-locking state and its magnetization is not synchronized with the magnetization of the movable junction 12. The linear dependence of the rectification voltage Vdc on the distance d between the junctions provides a valid procedure for determining the external acceleration applied to the accelerometer 10 starting from the measured voltage Vdc. This linear dependence, moreover, allows the accelerometer 10 according to the invention to detect acceleration without the need to resort to integration and differentiation operations of a measured signal.

Referring to FIG. 5, an accelerometer 110 in accordance with a further embodiment of the present invention comprises a first magnetic tunnel junction 111 and a second magnetic tunnel junction 115, both fixedly mounted and hereinafter referred to, for brevity, as first fixed junction 111 and second fixed junction 115. These first and second fixed junction are each mechanically coupled, by respective elastic means (not shown), to a further magnetic tunnel junction 112, movably mounted with respect to the aforementioned fixed junctions 111, 115 and hereinafter referred to, for brevity, as movable junction 112. In particular, the first and second fixed junction 111, 115 are constrained to respective supports 113, 116 fixedly mounted in a device comprising the accelerometer 110, while the movable junction 112 is constrained to a support 114 movable with respect to the aforementioned fixed supports 113, 116. The fixed supports 113, 116 are each mechanically connected with the movable support 114, by means of the aforementioned elastic means.

For the description of the tunnel junctions, please refer to what was illustrated above with reference to FIGS. 2a and 2b.

The movable support 114 is arranged between the two fixed supports 113, 116, such that the two fixed junctions 111, 115 and the movable junction 112 are substantially aligned. In such a configuration, the movable support 114 (and thus the movable junction 112) can move, under the action of an external acceleration, along the direction joining the movable junction 112 to the two fixed junctions 111, 115.

The first and second fixed junctions 111, 115 and the movable junction 112 are each advantageously connected to independent electrodes, which allow the current/voltage to be applied independently and allow the voltage to be read at the ends of the fixed junctions 111, 115 independently. The independent measurement of the voltage at the ends of the fixed junctions 111, 115 allows to guarantee a natural feedback and to increase the sensitivity of the accelerometer 110.

The first and second fixed junctions 111, 115 are also arranged at a distance from the movable junction 112 such as to be magnetically coupled to the movable junction 112, through the dipole interaction due to the magnetostatic fields generated by their ferromagnetic layers. The movable junction 112 may approach/move away from the first and second fixed junctions 111, 115 during the acceleration phases in a differential manner, i.e. approaching the first fixed junction 111 and moving away from the second fixed junction 115, or vice versa.

The first and second fixed junctions 111, 115 and the movable junction 112 are supplied, by a processing circuit (not shown) of the accelerometer 110, with a voltage and/or direct electric current sufficient to activate, in a known manner, a self-oscillating operating regime of the magnetization of their free layer. Thus, both the first and second fixed junctions 111, 115 and the movable junction 112 function as active spintronic diodes.

The two fixed junctions 111, 115 are also powered by an alternating electric current such that the fixed junctions 111, 115 are in the injection-locking state and rectifying voltages are generated at their ends, thanks to the spintronic diode effect.

In particular, according to the present embodiment, the frequency of oscillation of the magnetization of the free layer of the movable junction 112 in the self-oscillation state, induced by the sole introduction of a direct electric current, is different from the frequency of oscillation of the magnetization of the free layer of the fixed junctions 111, 115 in the injection-locking state. In such a situation, there are distances between fixed junctions 111, 115 and movable junction 112 such that the magnetic coupling causes the magnetization oscillations in the movable junction 112 to synchronize with the magnetization oscillations in the fixed junctions 111, 115. Such a condition is called mutual injection-locking state. Said synchronization induces a change in the phase and/or in the amplitude of the oscillations of the magnetization of the free layer of the fixed junctions 111, 115 which determines a variation of the rectification voltage read at the ends of the fixed junctions 111, 115.

In the absence of an external acceleration acting on the device on which the accelerometer 110 is mounted, the rectification voltage read at the ends of the fixed junctions 111, 115 is constant. When the accelerometer 110 is subjected to an acceleration, this determines a variation of the distances between the fixed junctions 111, 115 and the movable junction 112, which produces a variation in the magnetic coupling between the fixed junctions 111, 115 and the movable junction 112, which determines a variation of the rectifying voltage ΔVdc at the ends of the fixed junctions 111, 115. Based on the variation of rectification voltage ΔVdc detected by the processing circuit at the ends of the fixed junctions 111, 115 it is then possible to determine the acceleration that acted on the accelerometer 110.

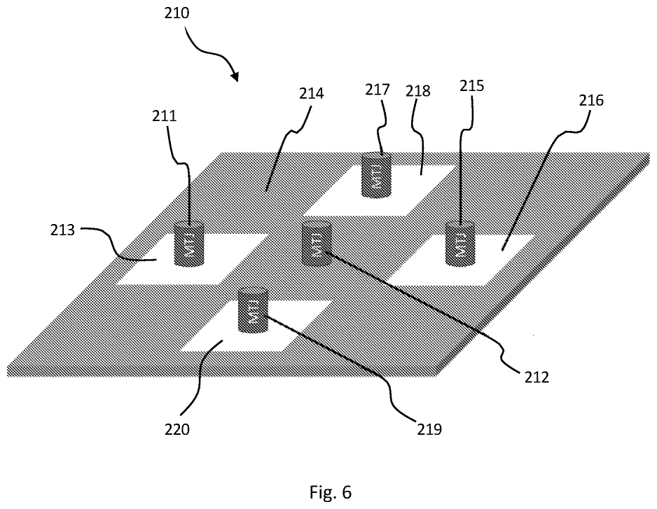

Referring to FIG. 6, an accelerometer 210 in accordance with a further embodiment of the present invention comprises a first, a second, a third and a fourth magnetic tunnel junction 211, 215, 217, 219 all fixedly mounted and hereinafter referred to, for brevity, as first fixed junction 211, second fixed junction 215, third fixed junction 217 and fourth fixed junction 219. These first, second, third and fourth fixed junctions 211, 215, 217, 219 are each mechanically coupled, by respective elastic means (not shown), to a further magnetic tunnel junction 212, movably mounted with respect to the aforementioned fixed junctions 211, 215, 217, 219 and hereinafter referred to, for brevity, as movable junction 212. In particular, the first, second, third and fourth fixed junction 211, 215, 217, 219 are constrained to respective supports 213, 216, 218, 220 fixedly mounted in a device comprising the accelerometer 210, while the movable junction 212 is constrained to a support 214 movable with respect to the aforementioned fixed supports 213, 216, 218, 220. The fixed supports 213, 216, 218, 220 are each mechanically connected with the movable support 214, by means of the aforementioned elastic means.

For the description of the tunnel junctions, please refer to what was illustrated above with reference to FIGS. 2a and 2b.

The fixed supports 213, 216, 218, 220 (and thus the fixed junctions 211, 215, 217, 219) are arranged in a cross configuration, i.e. in pairs aligned along two mutually orthogonal directions, with the movable support 214 (and thus the movable junction 212) placed in a central position with respect to the four fixed supports 213, 216, 218, 220. In such a configuration, the movable support 214 (and thus the movable junction 212) can move, under the action of an external acceleration, in a plane along the two mutually orthogonal directions joining the movable junction 212 to the four fixed junctions 211, 215, 217, 219.

The first, second, third and fourth fixed junctions 211, 215, 217, 219 and the movable junction 212 are each advantageously connected to independent electrodes, which allow the current/voltage to be applied independently and allow the voltage to be read at the ends of the fixed junctions 211, 215, 217, 219 independently. The independent measurement of the voltage at the ends of the fixed junctions 211, 215, 217, 219 allows to guarantee a natural feedback and to increase the sensitivity of the accelerometer 210.

The first, second, third and fourth fixed junctions 211, 215, 217, 219 are also arranged at a distance from the movable junction 212 such as to be magnetically coupled to the movable junction 212, through the dipole interaction due to the magnetostatic fields generated by their ferromagnetic layers. The movable junction 212 may approach/move away from the fixed junctions 211, 215, 217, 219 during the acceleration phases in a differential manner, i.e. approaching one or two fixed junctions and moving away from the remaining fixed junctions.

The first, second, third and fourth fixed junctions 211, 215, 217, 219 and the movable junction 212 are supplied, by a processing circuit (not shown) of the accelerometer 210, with a voltage and/or direct electric current sufficient to activate, in a known manner, a self-oscillating operating regime of the magnetization of their free layer. Thus, both the first, second, third and fourth fixed junctions 211, 215, 217, 219 and the movable junction 212 function as active spintronic diodes.

The first, second, third and fourth fixed junctions 211, 215, 217, 219 are also powered by an alternating electric current such that the fixed junctions 211, 215, 217, 219 are in the injection-locking state and rectifying voltages are generated at their ends, thanks to the spintronic diode effect.

In particular, according to the present embodiment, the frequency of oscillation of the magnetization of the free layer of the movable junction 212 in the self-oscillation state, induced by the sole introduction of a direct electric current, is different from the frequency of oscillation of the magnetization of the free layer of the fixed junctions 211, 215, 217, 219 in the injection-locking state. In such a situation, there are distances between fixed junctions 211, 215, 217, 219 and movable junction 212 such that the magnetic coupling causes the magnetization oscillations in the movable junction 212 to synchronize with the magnetization oscillations in the fixed junctions 211, 215, 217, 219. Such a condition is called mutual injection-locking state. Said synchronization induces a change in the phase and/or in the amplitude of the oscillations of the magnetization of the free layer of the fixed junctions 211, 215, 217, 219 which determines a variation of the rectification voltage read at the ends of the fixed junctions 211, 215, 217, 219.

In the absence of an external acceleration acting on the device on which the accelerometer 210 is mounted, the rectification voltage read at the ends of the fixed junctions 211, 215, 217, 219 is constant. When the accelerometer 210 is subject to acceleration, this causes a change in the distances between the fixed junctions 211, 215, 217, 219 and the movable junction 212, which causes a change in the magnetic coupling between the fixed junctions 211, 215, 217, 219 and the movable junction 212, which causes a change in the rectifying voltage ΔVdc at the ends of the fixed junctions 211, 215, 217, 219. Based on the variation in rectification voltage ΔVdc detected by the processing circuit at the ends of the fixed junctions 211, 215, 217, 219, it is then possible to determine the acceleration that acted on the accelerometer 210.

In accordance with a further embodiment of the present invention, not shown, an accelerometer may be provided with six fixed junctions arranged in aligned pairs along three mutually orthogonal directions, with the movable junction arranged centrally. In such a configuration, the movable junction can move, under the action of an external acceleration, in space along the three mutually orthogonal directions joining the movable junction to the six fixed junctions.

The description of the accelerometer with two and four fixed junctions applies, mutatis mutandis, to the present embodiment.

In accordance with a further embodiment of the present invention, not shown, the accelerometer comprises, in place of the movable junction of any of the preceding embodiments, a permanent magnet (e.g., NdFeB), mounted movable relative to the fixed junction(s).

Considering, for example, an embodiment with a single fixed junction, such a junction, as in the previous embodiment illustrated in FIG. 1, is made on a support fixedly mounted on a device comprising the accelerometer, while the permanent magnet is made on a support movable with respect to the aforementioned fixed support. The fixed support and the movable support are mechanically connected, by elastic means, in such a way that the movable support can move, under the action of an external acceleration, along the direction joining the permanent magnet and the fixed junction.

The fixed junction is powered, by means of an accelerometer processing circuit, both by a direct electric current/voltage, sufficient to activate, in a known way, the self-oscillating operating regime of the magnetization of its free layer, and by an alternating electric current, which determines the generation of a rectifying voltage, in a known way, thanks to the spintronic diode effect. Therefore, the fixed junction functions as a spintronic diode in active mode. The permanent magnet is mounted so that its magnetization is oriented along the axis connecting the permanent magnet and the fixed junction.

In the absence of an external acceleration acting on the device on which the accelerometer is mounted, the rectification voltage read at the ends of the fixed junction is constant. When the accelerometer is subjected to an acceleration, this causes a variation in the distance between the fixed junction and the movable magnet, which produces a variation in the magnetic coupling between the junction and the magnet, which causes a variation in the rectification voltage ΔVdc at the ends of the fixed junction. There are distances for which the rectification voltage depends linearly on the distance between the fixed junction and the moving magnet, so that the measurement of the variation of the rectification voltage ΔVdc detected by the processing circuit at the ends of the fixed junction allows the acceleration acting on the accelerometer to be determined.

The above description applies, mutatis mutandis, also to embodiments with two, four and six fixed junctions, by replacing the movable junction with a movable permanent magnet.

The magneto-mechanical accelerometer according to the illustrated embodiments, being free of magnetic tunnel junctions with flexible parts, is mechanically more robust than known spintronic and piezoresistive accelerometers based on the bending of some components following acceleration.

The magneto-mechanical accelerometer according to the embodiments illustrated above is easily scalable and can be integrated with a higher density. Thanks to the spintronic diode effect, the sensitivity of the accelerometer according to the invention can be higher than 200 kV/W, higher than the sensitivity of known MEMS-based accelerometers.

Moreover, thanks to the fact that the elements underlying the principle of operation of the accelerometer are of ferromagnetic origin, the accelerometer is immune to electromagnetic disturbances, unlike known accelerometers based on MEMS.

Finally, the use of magnetic junctions with a tunnel effect allows the creation of a low power, radiation resistant, high sensitivity and high frequency miniaturized accelerometer, compatible with CMOS.

1. Magneto-mechanical accelerometer comprising:
at least a first fixedly mounted magnetic tunnel junction, comprising a free ferromagnetic layer and a reference ferromagnetic layer,
a magnetic component mounted movable with respect to said at least a first magnetic tunnel junction, so that it can move close to/away from said at least a first magnetic tunnel junction during the acceleration phases to which the accelerometer is subjected, said magnetic component being either a further magnetic tunnel junction or a permanent magnet, wherein said at least a first magnetic tunnel junction and said magnetic component are coupled mechanically, by elastic means, and magnetically, by dipolar interaction due to the magnetostatic fields generated by said at least a first magnetic tunnel junction and said magnetic component, the accelerometer further comprising:
a processing circuit configured to: apply a direct electric voltage and/or current to said at least a first magnetic tunnel junction, said direct electric voltage and/or current being sufficient to activate the self-oscillating operating regime of the magnetization of the free ferromagnetic layer of said at least a first magnetic tunnel junction, apply an alternating electric current to said at least a first magnetic tunnel junction such that it induces an injection-locking state in said at least a first magnetic tunnel junction and induces a rectification voltage at the ends of said at least a first magnetic tunnel junction, due to the spintronic diode effect, measure the rectification voltage at the ends of said at least a first magnetic tunnel junction, and determine the acceleration to which the accelerometer is subjected on the basis of said measured rectification voltage.

2. Accelerometer according to claim 1, wherein said processing circuit is configured to determine the acceleration on the basis of said rectification voltage by comparing the change in rectification voltage with respect to a reference rectification voltage measured when there is no acceleration.

3. Accelerometer according to claim 1, wherein, in said at least a first magnetic tunnel junction, the reference ferromagnetic layer has fixed magnetization lying parallel to the reference ferromagnetic layer, and the free ferromagnetic layer has stable magnetization in a direction perpendicular to the free ferromagnetic layer and which varies in response to external stimuli.

4. Accelerometer according claim 1, wherein, in said further magnetic tunnel junction, a reference ferromagnetic layer has fixed magnetization lying parallel to said reference ferromagnetic layer, and a free ferromagnetic layer has stable magnetization in a direction perpendicular to said free ferromagnetic layer and which varies in response to external stimuli, wherein said processing circuit is configured to apply a direct electric voltage and/or current to said further magnetic tunnel junction, said direct electric voltage and/or current being sufficient to activate the self oscillating operating regime of the magnetization of the free ferromagnetic layer of said further magnetic tunnel junction and being such that it induces a mutual injection-locking state where the oscillation of the magnetization of the free ferromagnetic layer of said further magnetic tunnel junction synchronizes with the oscillation of the magnetization of the free ferromagnetic layer of said at least a first magnetic tunnel junction.

5. Accelerometer according to claim 1, further comprising a second fixedly mounted magnetic tunnel junction, wherein said magnetic component is placed between said first and second magnetic tunnel junction, such that said first and second magnetic tunnel junctions and said magnetic component are substantially aligned and said magnetic component can move, during the acceleration phases to which the accelerometer is subjected, along the direction joining said first and second magnetic tunnel junctions.

6. Accelerometer according to claim 1 further comprising a second, a third, and a fourth fixedly mounted magnetic tunnel junction, wherein said first, second, third and fourth magnetic tunnel junctions are arranged in pairs aligned along two mutually orthogonal directions, and wherein said magnetic component is placed in a central position with respect to said first, second, third and fourth magnetic tunnel junctions, so that said magnetic component can move, during the acceleration phases to which the accelerometer is subjected, in a plane along the two mutually orthogonal directions joining said first and second magnetic tunnel junctions and said third and fourth magnetic tunnel junctions, respectively.

7. Accelerometer according to claim 1, further comprising a second, a third, a fourth, a fifth and a sixth fixedly mounted magnetic tunnel junction, wherein said first, second, third, fourth, fifth and sixth magnetic tunnel junctions are arranged in pairs aligned along three mutually orthogonal directions, and wherein said magnetic component is placed in a central position with respect to said first, second, third, fourth, fifth and sixth magnetic tunnel junctions, so that said magnetic component can move, during the acceleration phases to which the accelerometer is subjected, in space along the three mutually orthogonal directions joining said first and second magnetic tunnel junctions, said third and fourth magnetic tunnel junctions and said fifth and sixth magnetic tunnel junctions, respectively.

8. Accelerometer according to claim 1, wherein said at least a first magnetic tunnel junction and said further magnetic tunnel junction are connected to independent electrodes.

9. Method for measuring acceleration using a magneto mechanical accelerometer according to claim 1, comprising the steps of:
applying a direct electric voltage and/or current to said at least a first magnetic tunnel junction, said direct electric voltage and/or current being sufficient to activate the self-oscillating operating regime of the magnetization of the free ferromagnetic layer of said at least a first magnetic tunnel junction,
applying an alternating electric current to said at least a first magnetic tunnel junction such that it induces an injection-locking state in said at least a first magnetic tunnel junction and induces a rectification voltage at the ends of said at least a first magnetic tunnel junction, due to the spintronic diode effect,
causing said magnetic component to move close to/away from said at least a first magnetic tunnel junction during the acceleration phases to which the accelerometer is subjected, measuring the rectification voltage at the ends of said at least a first magnetic tunnel junction; determining the acceleration to which the accelerometer is subjected on the basis of said measured rectification voltage.

10. Method according to claim 9, wherein the step of determining the acceleration on the basis of said rectification voltage includes comparing the change in rectification voltage with respect to a reference rectification voltage measured when there is no acceleration.
